(19) United States
(12) Patent Application Publication
(10) Pub. No.: US 2024/0162097 A1
(43) Pub. Date: May 16, 2024

(54) PROCESS MONITORING STRUCTURES FOR VIA ETCH PROCESSES FOR SEMICONDUCTOR DEVICES

(71) Applicant: Systems on Silicon Manufacturing Company Pte Ltd, Singapore (SG)

(72) Inventors: Yan Luo, Singapore (SG); René Wientjes, Cuijk (NL); Poh Cheng Tan, Singapore (SG); Deo Brat Singh, Singapore (SG); Sudeep Gudla, Singapore (SG)

(21) Appl. No.: 18/055,420

(22) Filed: Nov. 15, 2022

(51) Int. Cl. H01L 21/66; H01L 21/768; H01L 23/50; H01L 23/522; H01L 23/528

(52) U.S. Cl. CPC H01L 22/32; H01L 21/76831; H01L 22/14; H01L 23/50; H01L 23/5226; H01L 23/528

(57) ABSTRACT

The present disclosure relates to a semiconductor device. The semiconductor device includes semiconductor substrate and a BEOL dielectric having x number of intermetal dielectric (IMD) layers, wherein an i^{th} ILD layer, where i=1 to x, includes a metal dielectric layer Mi with metal lines, and a via dielectric layer Vi above the Mi, the via dielectric layer includes via contacts, the via contacts are coupled to metal lines of Mi and Mi+1. The semiconductor device also includes a process control monitoring (PCM) structure for monitoring via contact landing of via contacts of Vi landing on metal lines of Mi. The PCM structure includes a lower PCM interconnect disposed on Mi. The PCM structure also PCM via contacts, wherein the PCM via contacts are disposed proximately to the lower metal interconnect and extend below a top surface of the lower PCM interconnect by an overlap distance OV, the PCM via contacts are separated by dielectric of Mi. The PCM structure further includes an upper PCM interconnect disposed on Mi+1, wherein the upper interconnect is coupled to top surfaces of the PCM via contacts. The PCM structure forms a via chain capacitor which is configured to generate a PCM capacitance indicating a depth of the via contacts of Vi with respect to metal lines of Mi when a PCM test voltage is applied to the PCM structure.

### BACKGROUND

In integrated circuits (ICs), back-end-of-line (BEOL) processing forms metal lines in metallization layers to interconnect circuit components, such as transistors, resistors, and capacitors formed on a substrate. For example, inter-metal dielectric (IMD) layers include via contacts which interconnect the metal lines of different metallization layers to interconnect the circuit components.

An IMD level, for example, includes a metal level dielectric with metal lines or interconnects and a via dielectric level with via contacts above. Via contacts are formed by forming via openings in the via dielectric level. The via opening exposes the metal lines of the metal level below. For example, the via opening lands on the metal lines below. The via openings are filled with metal to form the via contacts, connecting to the metal lines below.

Generally, a timed etch is performed to form the via opening which lands on the metal lines below. The duration of the timed etch ensures that the via opening exposes the metal lines below. However, over time, the etch tool parameters may drift. For example, the drift may result in the etch not sufficiently or not exposing the metal lines below. For example, unlanded or insufficiently landed via contacts are formed in the via openings. This causes high resistance connections or even open connections, impacting performance or even functionality of the device. Furthermore, for high frequency circuits, there is a need to increase the thickness of the IMD layers. This further exacerbates the via opening process, making it more prone to unlanded via contacts.

From the foregoing discussion, it is desirable to reliably determine when via opening etch processes can drift to far from target to prevent unlanded or insufficiently unlanded via contacts to ensure proper functioning of devices.

### SUMMARY

Embodiments of the present disclosure generally relate to semiconductor device and method of forming thereof.

In one embodiment, a semiconductor device includes a semiconductor substrate. The semiconductor substrate includes circuit components disposed on an active surface thereof. The semiconductor device also includes a BEOL dielectric having x number of intermetal dielectric (IMD) layers, wherein an i^{th} ILD layer, where i=1 to x, includes a metal dielectric layer Mi with metal lines, and a via dielectric layer Vi above the Mi. The via dielectric layer includes via contacts, the via contacts are coupled to metal lines of Mi and Mi+1. The semiconductor device further includes a process control monitoring structure for monitoring via contact landing of via contacts of Vi landing on metal lines of Mi. The PCM structure includes a lower PCM interconnect disposed on Mi. The PCM structure also includes PCM via contacts, wherein the PCM via contacts are disposed proximately to the lower metal interconnect and extend below a top surface of the lower PCM interconnect by an overlap distance OV, the PCM via contacts are separated by dielectric of Mi. The PCM structure further includes an upper PCM interconnect disposed on Mi+1, wherein the upper interconnect is coupled to top surfaces of the PCM via contacts. The PCM structure forms a via chain capacitor which is configured to generate a PCM capacitance indicating a depth of the via contacts of Vi with respect to metal lines of Mi when a PCM test voltage is applied to the PCM structure.

In another embodiment, a method for forming a semiconductor device includes providing a semiconductor substrate. The semiconductor substrate includes circuit components disposed on an active surface thereof. The method also includes forming a BEOL dielectric having x number of intermetal dielectric (IMD) layers, wherein forming an i^{th} ILD layer, where i=1 to x, includes forming a metal dielectric layer Mi with metal lines, and forming a via dielectric layer Vi above the Mi, the via dielectric layer includes via contacts, the via contacts are coupled to metal lines of Mi and Mi+1. The method further includes forming a metal dielectric layer Mi+1 with metal lines. Forming the i^{th} ILD layer and Mi+1 also includes forming a process control monitoring (PCM) structure (PCM) for monitoring via contact landing of via contacts of Vi landing on metal lines of Mi. Forming the PCM structure includes forming a lower PCM interconnect disposed on Mi. Forming the PCM structure also includes forming PCM via contacts. The PCM via contacts are disposed proximately to the lower metal interconnect and extend below a top surface of the lower PCM interconnect by an overlap distance OV, the PCM via contacts are separated by dielectric of Mi. Forming the PCM structure further includes forming an upper PCM interconnect disposed on Mi+1. The upper interconnect is coupled to top surfaces of the PCM via contacts to form a via chain capacitor. The method also includes applying a test voltage to the PCM structure and measuring the PCM capacitance which indicates a depth of the PCM via contacts relative to the PCM lower interconnect.

In yet another embodiment, a method for forming a semiconductor device includes providing a semiconductor wafer. The semiconductor wafer includes a plurality of devices with circuit components disposed on an active surface thereof. The devices arranged in a matrix of devices with rows and columns, wherein the devices are separated by a kerf region between rows and columns of devices. The method also includes forming a BEOL dielectric for the devices having x number of intermetal dielectric (IMD) layers, wherein forming an i^{th} ILD layer, where i=1 to x, includes forming a metal dielectric layer Mi with metal lines, and forming a via dielectric layer Vi above the Mi. The via dielectric layer includes via contacts, the via contacts are coupled to metal lines of Mi and Mi+1. The method further includes forming a metal dielectric layer Mi+1 with metal lines. Forming the i^{th} ILD layer and Mi+1 for the devices also includes forming process control monitoring (PCM) structures for monitoring via contact landing of via contacts of Vi landing on metal lines of Mi for the devices. The PCM structures for the devices are formed in the kerf region of the wafer. Forming the PCM structures includes forming lower PCM interconnects disposed on Mi for the devices. Forming the PCM structures also includes forming PCM via contacts. The PCM via contacts are disposed proximately to the lower metal interconnects and extend below a top surface of the lower PCM interconnects by an overlap distance OV, the PCM via contacts are separated by dielectric of Mi. Forming the PCM structures further includes forming upper PCM interconnects disposed on Mi+1, wherein the upper interconnects are coupled to top surfaces of the PCM via contacts to form via chain capacitors. The method also includes applying a test voltage to the PCM structures and measuring the PCM capacitance which indicates a depth of the PCM via contacts relative to the PCM lower interconnect.

These and other advantages and features of the embodiments herein disclosed, will become apparent through reference to the following description and the accompanying drawings. Furthermore, it is to be understood that the features of the various embodiments described herein are not mutually exclusive and can exist in various combinations and permutations.

### BRIEF DESCRIPTION OF THE DRAWINGS

The accompanying drawings, which are incorporated in and form part of the specification in which like numerals designate like parts, illustrate preferred embodiments of the present disclosure and, together with the description, serve to explain the principles of various embodiments of the present disclosure.

FIG. 1a shows a simplified top view of a wafer processed with devices;

FIG. 1b shows a simplified cross-sectional view of a portion of an embodiment of a device; and

FIGS. 2a-2c show various simplified cross-sectional views of the BEOL dielectric of a portion of a device;

FIGS. 3a-3b show cross-sectional and top views of process control structures for monitoring etch depth of a via opening process to ensure overetching to expose the metal lines below;

FIG. 4 is a table illustrating various levels of the BEOL dielectric related to monitoring different etch depths of different via levels;

FIG. 5 shows a graph indicating the effectiveness of embodiments of the monitoring structures.

### DETAILED DESCRIPTION

Embodiments generally relate to semiconductor devices, such as integrated circuits (ICs). More particularly, embodiments relate to reliable interconnects in ICs. More particularly, embodiments relate to process control or test structures for monitoring via etch processes to ensure sufficient via depth etch. The structures are employed in processing to form reliable interconnects in ICs. The ICs can be any types of ICs. The devices or ICs may be incorporated into or used with, for example, consumer electronic products, or other types of products.

Semiconductor fabrication, such as complementary metal oxide semiconductor (CMOS) fabrication, forms a plurality of devices on a wafer in parallel. The fabrication process may involve the formation of features on the wafer which correspond to the circuit components, such as transistors, resistors, and capacitors. The devices are interconnected, enabling the IC to perform the desired functions. After wafer processing is completed, the wafer is diced to singulate the devices.

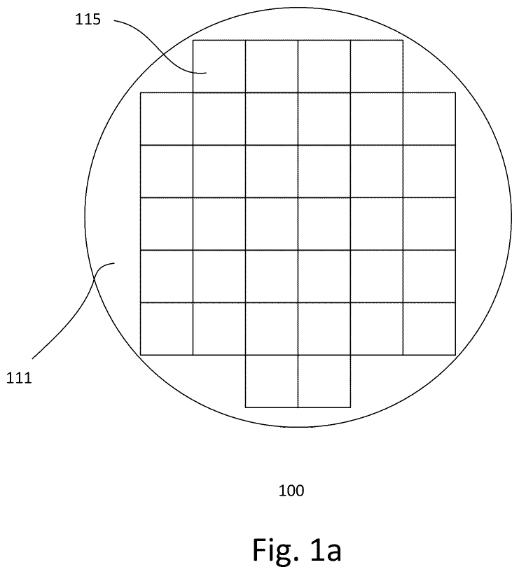

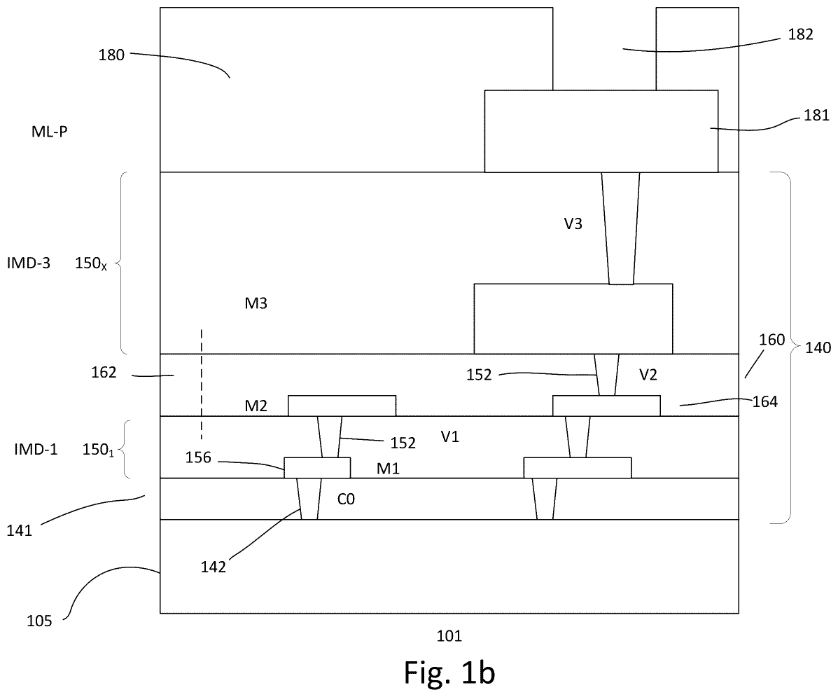

FIG. 1a shows a simplified top view of an embodiment of a semiconductor wafer 100. The semiconductor wafer may be a silicon wafer. Other types of wafers may also be useful. The wafer includes an active surface 111 on which devices 115 are formed in parallel. The devices, for example, are arranged in rows along a first (x) direction and columns along a second (y) direction. Separating the devices are through dicing channels. The dicing channels may be referred to as the kerf region of the wafer. After processing is completed, the wafer is diced along the dicing channels to singulate the devices into individual chips.

FIG. 1b shows a simplified cross-sectional view of a portion of an exemplary embodiment of a device 101. The device is formed on a substrate 105. The substrate, for example, is a part of a semiconductor wafer, such as a silicon wafer. The wafer may be a lightly doped p-type wafer. Other types of wafers, such as a silicon-on-insulator (SOI), or silicon germanium wafer as well as a wafer doped with other types of dopants or dopant concentrations may also be useful.

The substrate is processed to form different device regions with components. For example, front-end-of-line (FEOL) processing is performed on the substrate. FEOL processing may include forming isolation regions to isolate different device regions. The device regions may include high voltage (HV), low voltage (LV) and intermediate or medium voltage (MV) regions or a combination thereof. High voltage devices or components are formed in the high voltage region, low voltage components are formed in the low voltage region and intermediate voltage components are formed in the intermediate voltage region. The components may be metal oxide semiconductor (MOS) transistors. Other types of components or device regions may also be useful. For example, resistor and/or capacitor regions may be formed for resistors and capacitors. The isolation regions may be shallow trench isolation (STI) regions. Other types of isolation regions may also be useful. The isolation regions are provided to isolate device regions from other regions. The FEOL processing may further include forming device wells which may be formed for p-type and n-type transistors for a complementary MOS (CMOS) device. Separate implants may be employed to form different doped wells using, for example, implant masks, such as photoresist masks.

After forming the wells, gates of transistors may be formed on the substrate. The gates are formed by, for example, forming a gate oxide layer, such as a thermal silicon oxide layer, followed by a gate electrode layer, such as a polysilicon layer. The gate electrode may be doped. Other types of gate materials may also be useful. Separate processes may be performed for forming gate dielectrics of the different voltage transistors. This is due to, for example, different gate oxide thicknesses associated with the different voltage transistors. For example, an HV transistor will have a thicker gate dielectric than an LV transistor. The gate layers may be patterned to form gates. For example, a photoresist mask may be used for a reactive ion etch (RIE) to pattern the gate layers to form the gates.

After forming the gates, source/drain (S/D) regions are formed adjacent to the gates. The S/D regions are heavily doped regions. Depending on the type of device, the S/D regions may be heavily doped n-type or p-type regions. For n-type transistors, S/D regions are heavily doped n-type regions, and for p-type transistors, S/D regions are heavily doped p-type regions. Lightly doped regions may be provided for the S/D regions. Dielectric sidewall spacers may be provided on sidewalls of the gates to facilitate forming lightly doped regions. Separate implants may be employed to form different doped regions using, for example, implant masks, such as photoresist masks. Other types of components may also be formed, such as capacitors and resistors.

Back-end-of-line (BEOL) processing is performed after forming the transistors. The BEOL process includes forming a BEOL dielectric 140 with interconnects. The interconnects connect the various components of the IC to perform the desired functions. The BEOL dielectric includes a plurality of intermetal dielectric (IMD) levels 150₁₋ₓ. As shown, the BEOL dielectric includes 3 IMD levels (IMD-1 to IMD-3). For example, as shown, x=3. Providing other number of IMD levels for the BEOL dielectric layer also be useful.

An IMD level includes an IMD dielectric 160. The IMD dielectric includes a metal level dielectric 164 and a via dielectric 162. Metal lines or interconnects 156 are disposed in the metal level dielectric and via contacts 152 are provided in the via dielectric. For example, the first IMD level IMD-1 includes a first metal dielectric M1 below a first via dielectric V1. The via contacts of a via level Vᵢ couples metal lines of a metal level below Mi and above Mi+1, wherein i is from 1 to x. For example, an i^{th} level of an IMD, metal or via level of the BEOL dielectric is from 1 to x, where x is equal to the highest level.

Below the IMD level is a pre-metal dielectric 141. The pre-metal dielectric may be referred to as CO and includes pre-metal via contacts 142. The pre-metal via contacts are coupled to contact regions on the substrate. The substrate contact regions may include S/D regions and gates of transistors, well taps, as well as other types of contact regions, including electrodes of capacitors and resistors.

Above the AVID level is a pad metal dielectric ML-P with metal pads 181. The metal ML-P level may be considered the upper most metal level above the upper most IMD level. For example, the ML-P level is equal to metal level Mx+1. The pad metal level dielectric may include a passivation dielectric 180 which covers the metal pads. The passivation dielectric may include a plurality of dielectrics, forming a passivation stack. The passivation stack may include silicon oxide, silicon nitride, silicon oxynitride or other types of dielectric layers. Pad openings 182 are provided to expose the pads for external connection to the device.

In one embodiment, pad metal lines 181 of a pad metallization level (ML-P) are disposed on the top dielectric layer of IMD-3. The pad metal lines, for example, may be aluminum pad lines and have similar dimensions as the upper metal lines. For example, the pad metal lines may have relaxed CD compared to the lower metal lines of the lower metallization levels. A passivation layer 180 is disposed over the pad metal lines and IMD-4. In one embodiment, the passivation layer is silicon oxide. In some cases, the passivation layer may be a passivation stack having multiple passivation layers. For example, a combination of silicon oxide and silicon nitride can be used for the multiple passivation layers. Other configurations of the passivation stack may also be useful. Pad openings 182 are provided in the passivation layer to expose pad positions of the pad metal lines.

The IMD layers and pre-metal layers may be silicon oxide layers or other types of dielectric layers. The IMD layers of the different AVID levels, although not necessary, may be the same type of dielectric layers. As for the metal lines and via contacts, they may be formed of tungsten, aluminum, copper or other types of conductive materials. For example, the metal lines may be aluminum lines while contacts may be tungsten contacts. Providing other types of metal lines or contacts may also be useful. The metal lines of the different AVID levels may be the same type of metal lines, such as aluminum lines; the contacts of the different IMD levels may be the same type of contacts, such as tungsten contacts. Other configurations of the metal lines and contacts of the IMD levels may also be useful. For example, it is not necessary for the different IMD levels to have the same type of metal lines and the same type of contacts. In addition, etch stop layers may be provided within the BEOL dielectric. For example, etch stop layers may be provided between dielectrics and/or metal layers. Various techniques may be employed to form the dielectric and metal layers. For example, chemical vapor deposition (CVD) may be employed to form the dielectric layers. As for the metal layers, they may be formed by sputtering, plating or CVD.

As shown, lower IMD layers are thinner than the upper IMD layers. The interconnects and contacts of the IMD levels may be formed using various techniques, such as single damascene, dual damascene and reactive ion etch (RIE) processes. Other configurations and techniques for forming the BEOL dielectric may also be useful.

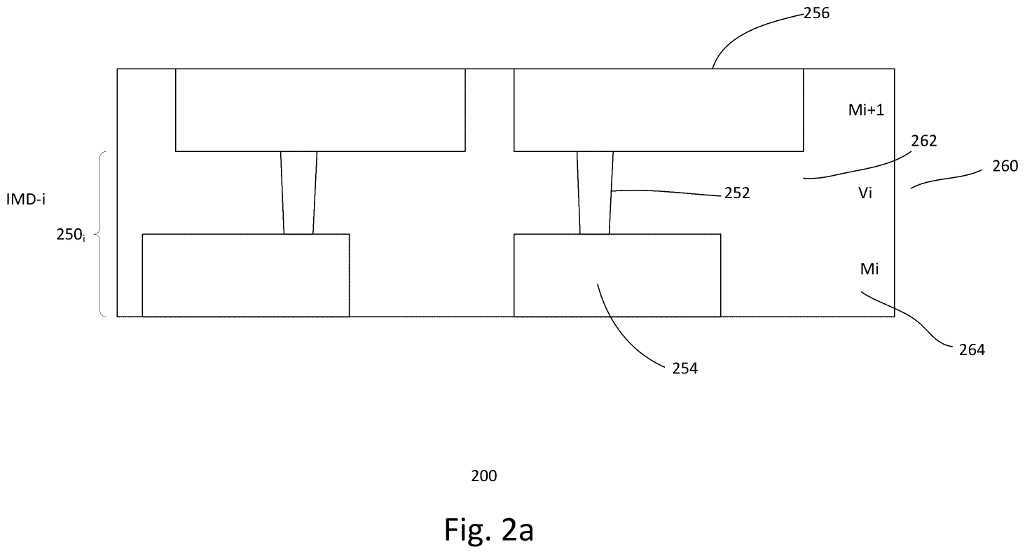

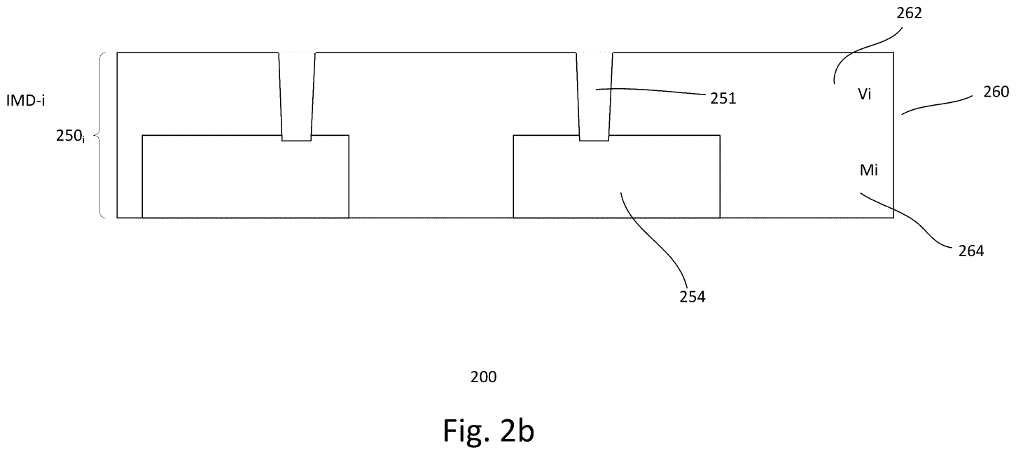

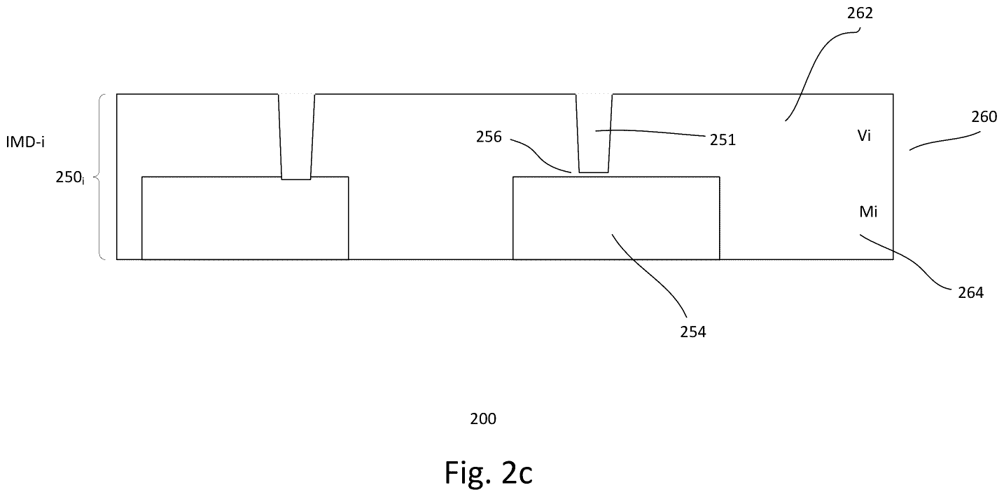

FIGS. 2a-2c show various simplified cross-sectional views of the BEOL dielectric of a portion of a device. Referring to FIG. 2a, the portion of the device includes an IMD 250, level with Mi and Vᵢ and a metal layer Mi+1 above. For example, IMD-i includes a metal dielectric 264 with metal interconnects 256 and a via dielectric 262 with via contacts 252. The via contacts of Vi connect interconnects of Mi to Mi+1 metal dielectrics. As discussed, an import issue is that the via contacts at Vi land sufficiently on the metal interconnects of Mi. Insufficient landing causes high contact resistance, impacting performance or even functionality of the device.

In FIG. 2b, IMD-i is shown. As shown, via dielectric Vi is processed by etching via openings 251 to interconnects 254 of metal dielectric Mi below. Based on the timed etch configured according to the etch recipe, the via opening overetches the via dielectric Vi to ensure that the via contact which is subsequently formed contacts the interconnects.

However, as shown, in FIG. 2c, due to drift in the etch tool, the timed etch may not sufficiently expose the metal interconnect of Mi. For example, dielectric 256 of the via dielectric Vi may remain to cover the interconnect 254 of Mi. This can result in high resistance contact or an open connection between the via contacts and the interconnect.

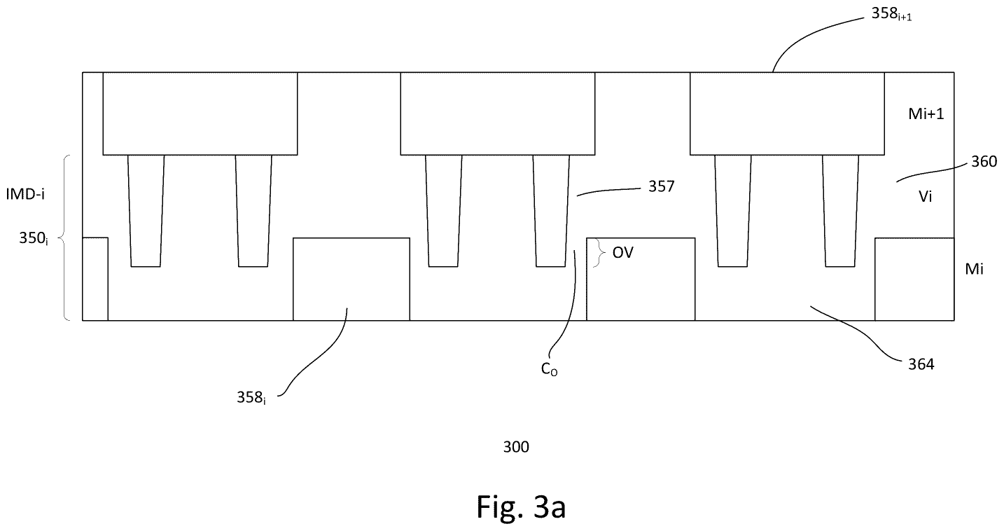

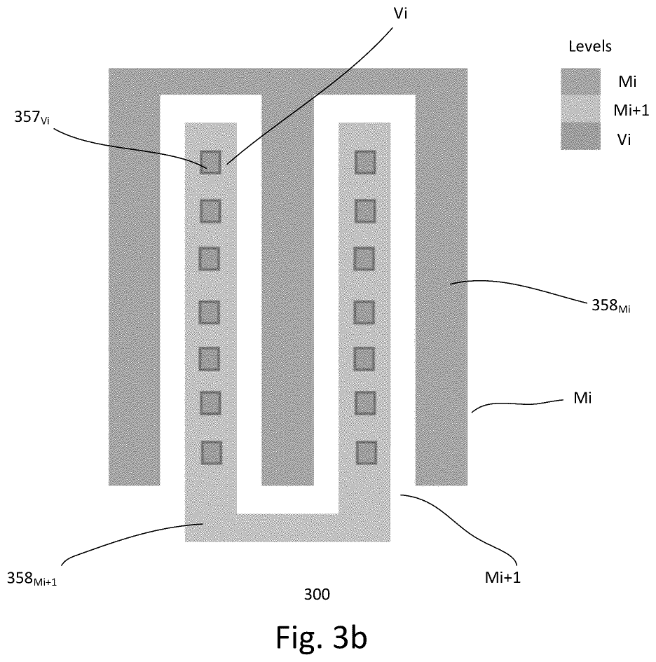

FIG. 3a shows a simplified cross-sectional view of an embodiment of a process control monitoring (PCM) structure 300 for monitoring etch depth of a via opening process to ensure overetching to expose metal lines below. In one embodiment, the test structure or structures are located in the kerf region of the wafer. This avoids unnecessary wafer area for PCM test structures, minimizing valuable wafer real estate.

In one embodiment, the PCM test structure is a capacitive PCM structure. For example, the capacitive PCM structure is configured to utilize a via-metal overlap capacitance to monitor a depth of the via structure in the via dielectric with respect to the metal level dielectric below. For example, the PCM structure measures the overlap capacitance of a via contact at Vi with respect to a metal interconnect at Mi. In one embodiment, the PCM test structure is configured as a via chain capacitor structure which measures the overlap capacitances of a chain of via contacts at Vi with respect to a metal interconnect at Mi.

As shown, a lower metal interconnect 358ᵢ is disposed in the metal dielectric Mi. In one embodiment, the lower metal interconnect forms a first capacitor plate of the via chain capacitor. Via contacts 357_{VX} are disposed in the via dielectric Vi. As shown, via contacts are configured as double contacts. For example, first and second contacts are provided for overlapping between adjacent portions of the lower metal interconnects. Other configurations of the via contacts, such as single via contacts, may also be useful. The via contacts are connected by an upper metal interconnect 358ᵢ₊₁ in the metal dielectric Mᵢ₊₁ to form a via contact chain. In one embodiment, the upper metal interconnect slightly overlaps the lower metal interconnect. Providing non-overlapping upper and lower metal interconnects may also be useful.

The via contacts, as shown, are disposed adjacent to the lower metal interconnect without contacting it. In one embodiment, the via contacts overlap the lower metal interconnect by an overlap depth OV. In one embodiment, the overlap of the via contacts with the lower metal interconnect generates an overlap capacitance Co for the test structure. The value of Co varies depending on the depth of the overlap between the via contacts and lower interconnect, for a given test structure. For example, different test structures may be configured with different overlap capacitances. The overlap capacitance, for example, depends on the structure as well as the intermediate dielectric (ILD) layer in which it is disposed. In one embodiment, Co is defined within a threshold range. The threshold range is based on the desired depth range of the overlap between the via contacts and the lower metal interconnect. For example, if Co is outside of the range, the process has drifted such that the via opening is either too deep or too shallow. In the case that the via is too deep, too much metal is eroded from the interconnect. On the other hand, if the via is getting too shallow, this indicates that the etch tool has drifted and the etch process needs to be adjusted to avoid over-etching or under-etching which can negatively affect yields. For example, the etch process can be adjusted by adjusting chemistry or power to avoid over-etching or under-etching. Other methods suitable for adjusting etch processes to avoid over-etching or under-etching may also be useful.

In one embodiment, the capacitance of the test structure can be measured by applying a continuous voltage pulse between the upper and lower interconnects. For example, a continuous voltage pulse of 3.3 V is applied. For example, one interconnect is connected to the positive or high potential and the other interconnect is connected to ground or low potential. The voltage and current are measured within a pulse cycle. The capacitance C is calculated based on C=Q/V. For example, C=(measured current I*period)/measure voltage V.

FIG. 3b shows a simplified top view of an embodiment of a PCM test structure for monitoring via etch process. As shown, the lower interconnect 358_{X} at metal dielectric level M_{X} is an M-shaped or double U-shaped interconnect while the upper interconnect 358_{X+1} at metal dielectric level M_{X+1} is U-shaped. For example, the upper interconnect is mated to the lower interconnect. As shown, the upper and lower interconnects do not overlap. Providing overlapping upper and lower interconnects may also be useful. As shown, via contacts 357_{VX} at via dielectric level V_{X} are coupled to the upper interconnect. The via contacts, for example, are configured as single via contacts. Providing double via contacts may also be useful. A depth of the via contacts overlap the lower interconnects, forming the via chain capacitor PCM structure.

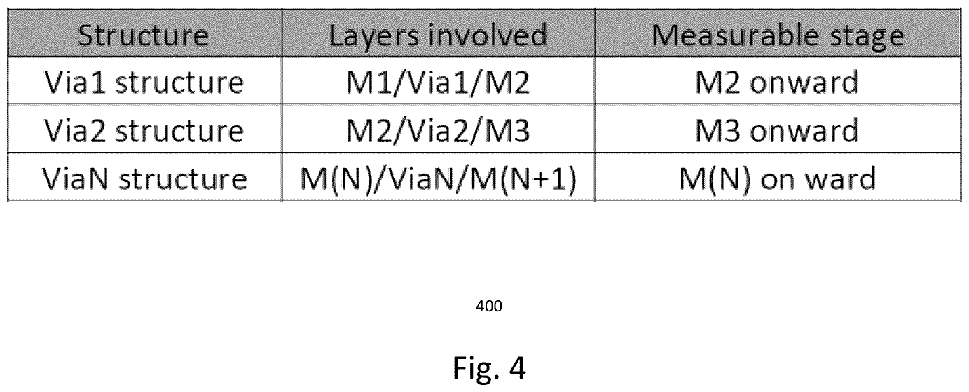

FIG. 4 shows a table indicating the layers involved for a PCM structure configured for monitoring the via contact landing on the metal level below. The device, in one embodiment, includes PCM structures for monitoring via contact landing of all via dielectric levels of the BEOL dielectric. For example, to measure contact landing of via level V1, the PCM structure is formed in the M1, V1 and M2 layers of the BEOL dielectric. The capacitance can be measured at M2 and above. For example, the capacitance of the PCM structure can be measured at any metal level at or above M2. To measure contact landing of via contacts at V2, the PCM structure is formed in M2, V2 and M3. The capacitance of via contacts at V2 can be measured at metal level M3 or above. As for measuring contact landing of via contacts at V3, the PCM structure is formed in M3, V3 and M4 and capacitance can be measured at metal level M3 or above.

As discussed, the PCM structures are located in the Kerf region of the wafer. The measurements can be configured to measure at the same level. For example, the PCM structures on the wafer can be measured after the PCM for the final via contact level is formed. Other configurations for measuring the PCM structures may also be useful. For example, capacitance may be measured after each PCM structure for each via level is formed.

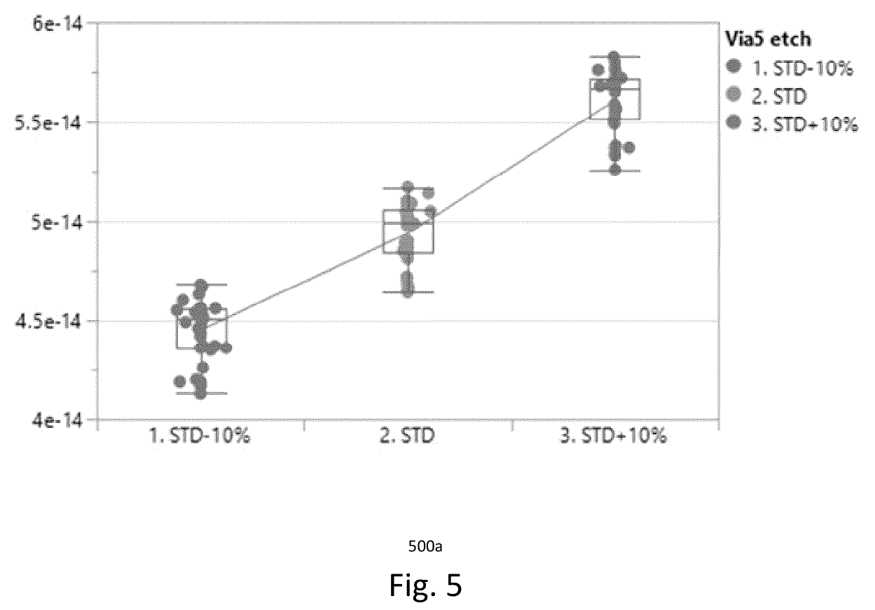

FIG. 5 shows a graph indicating the effectiveness of embodiments of the PCM monitoring structures. An experiment was conducted to test the effectiveness of the PCM monitoring structures. The PCM structures were configured to measure via contact landing at via level V5. For example, the PCM structures were formed at M5, V5 and M6. Silicon wafers were prepared with BEOL dielectric which includes PCM structures formed to measure via contact landing at level V5. Via etch times were varied for different wafers. The capacitance was measured from PCM structures of the different wafers and plotted in the graph in FIG. 5. As shown, for different time splits, different capacitance values were measured. As such, the PCM structures can detect depth variations.

The present disclosure may be embodied in other specific forms without departing from the spirit or essential characteristics thereof. The foregoing embodiments, therefore, are to be considered in all respects illustrative rather than limiting the invention described herein. The scope of the invention is thus indicated by the appended claims, rather than by the foregoing description, and all changes that come within the meaning and range of equivalency of the claims are intended to be embraced therein.

What is claimed is:

1. A semiconductor device comprising:
a semiconductor substrate, wherein the semiconductor substrate includes circuit components disposed on an active surface thereof;
a BEOL dielectric having x number of intermetal dielectric (IMD) layers, wherein an i^{th} ILD layer, where i=1 to x, includes
a metal dielectric layer Mi with metal lines, and
a via dielectric layer Vi above the Mi, the via dielectric layer includes via contacts, the via contacts are coupled to metal lines of Mi and Mi+1; and
a process control monitoring structure for monitoring via contact landing of via contacts of Vi landing on metal lines of Mi, the PCM structure includes
a lower PCM interconnect disposed on Mi,
PCM via contacts, wherein the PCM via contacts are disposed proximately to the lower metal interconnect and extend below a top surface of the lower PCM interconnect by an overlap distance OV, the PCM via contacts are separated by dielectric of Mi,
an upper PCM interconnect disposed on Mi+1, wherein the upper interconnect is coupled to top surfaces of the PCM via contacts, and
wherein the PCM structure forms a via chain capacitor which is configured to generate a PCM capacitance indicating a depth of the via contacts of Vi with respect to metal lines of Mi when a PCM test voltage is applied to the PCM structure.

2. The semiconductor device of claim 1 further comprises a pre-metal dielectric below M1, pre-metal via contacts coupled to M1 metal lines and contact regions on the active surface of the substrate.

3. The semiconductor device of claim 1 further comprises a pad metal (MP) dielectric with metal pads above Mx, the PCM via contacts of Vx are coupled to the upper PCM interconnect in the MP.

4. The semiconductor device of claim 1, wherein the lower PCM interconnect is an M-shaped or double U-shaped interconnect, the upper interconnect is a U-shaped interconnect.

5. The semiconductor device of claim 1, wherein the semiconductor device is a part of a wafer with a plurality of semiconductor devices separated by a kerf region, wherein the PCM structures are disposed in the kerf region of the wafer between the semiconductor devices.

6. A method for forming a semiconductor device comprising:
providing a semiconductor substrate, wherein the semiconductor substrate includes circuit components disposed on an active surface thereof;
forming a BEOL dielectric having x number of intermetal dielectric (IMD) layers, wherein forming an i^{th} ILD layer, where i=1 to x, includes
forming a metal dielectric layer Mi with metal lines, and
forming a via dielectric layer Vi above the Mi, the via dielectric layer includes via contacts, the via contacts are coupled to metal lines of Mi and Mi+1;
forming a metal dielectric layer Mi+1 with metal lines;
wherein forming the i^{th} ILD layer and Mi+1 also includes forming a process control monitoring (PCM) structure for monitoring via contact landing of via contacts of Vi landing on metal lines of Mi, wherein forming the PCM structure includes
forming a lower PCM interconnect disposed on Mi,
forming PCM via contacts, wherein the PCM via contacts are disposed proximately to the lower metal interconnect and extend below a top surface of the lower PCM interconnect by an overlap distance OV, the PCM via contacts are separated by dielectric of Mi,
forming an upper PCM interconnect disposed on Mi+1, wherein the upper interconnect is coupled to top surfaces of the PCM via contacts to form a via chain capacitor;
and
applying a test voltage to the PCM structure and measuring the PCM capacitance which indicates a depth of the PCM via contacts relative to the PCM lower interconnect.

7. The method of claim 6, wherein the PCM structures are disposed in all IMD levels.

8. The method of claim 6, wherein the PCM structures are disposed in at least one IMD level.

9. The method of claim 6, wherein applying the test voltage to the PCM structure is performed after each PCM structure for each level is completed.

10. The method of claim 6, wherein applying the test voltage to the PCM structure is performed after PCM structures for all levels are completed.

11. A method for forming a semiconductor device comprising:
providing a semiconductor wafer, wherein the semiconductor wafer includes a plurality of devices with circuit components disposed on an active surface thereof, the devices are arranged in a matrix of devices with rows and columns, wherein the devices are separated by a kerf region between rows and columns of devices;
forming a BEOL dielectric for the devices having x number of intermetal dielectric (IMD) layers, wherein forming an i^{th} ILD layer, where i=1 to x, includes
forming a metal dielectric layer Mi with metal lines, and
forming a via dielectric layer Vi above the Mi, the via dielectric layer includes via contacts, the via contacts are coupled to metal lines of Mi and Mi+1;
forming a metal dielectric layer Mi+1 with metal lines;
wherein forming the i^{th} ILD layer and Mi+1 for the devices also includes forming process control monitoring (PCM) structures for monitoring via contact landing of via contacts of Vi landing on metal lines of Mi for the devices, wherein the PCM structures for the devices are formed in the kerf region of the wafer, wherein forming the PCM structures includes
forming lower PCM interconnects disposed on Mi for the devices,
forming PCM via contacts, wherein the PCM via contacts are disposed proximately to the lower metal interconnects and extend below a top surface of the lower PCM interconnects by an overlap distance OV, the PCM via contacts are separated by dielectric of Mi,
forming upper PCM interconnects disposed on Mi+1, wherein the upper interconnects are coupled to top surfaces of the PCM via contacts to form via chain capacitors;
and
applying a test voltage to the PCM structures and measuring the PCM capacitance which indicates a depth of the PCM via contacts relative to the PCM lower interconnect.

12. The method of claim 11, wherein the PCM structures are disposed in all AVID levels.

13. The method of claim 11, wherein the PCM structures are disposed in at least one IMD level.

14. The method of claim 11, wherein applying the test voltage to the PCM structure is performed after each PCM structure for each level is completed.

15. The method of claim 11, wherein applying the test voltage to the PCM structure is performed after PCM structures for all levels are completed.
